(19) United States
(12) Patent Application Publication
(10) Pub. No.: US 2025/0014863 A1
(43) Pub. Date: Jan. 9, 2025

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 18/754,488

(22) Filed: Jun. 26, 2024

(30) Foreign Application Priority Data
Jul. 7, 2023 (JP) 2023-112264

(51) Int. Cl. H01J 37/32

(52) U.S. Cl. CPC H01J 37/32082

(57) ABSTRACT

A plasma processing apparatus includes: a chamber including a processing space inside the chamber; a substrate support installed in the processing space; an excitation electrode installed above the substrate support; a discharger configured to discharge electromagnetic waves into a plasma generation space below the excitation electrode; and a resonator installed on the excitation electrode and electromagnetically coupled to the discharger. The resonator includes a waveguide path including a plurality of folded portions between a first end and a second end of the resonator. At least one adjustor configured to adjust a resonance frequency of the electromagnetic waves propagating in the waveguide path is installed in the waveguide path.

### CROSS-REFERENCE TO RELATED APPLICATION

This application is based upon and claims the benefit of priority from Japanese Patent Application No. 2023-112264, filed on Jul. 7, 2023, the entire contents of which are incorporated herein by reference.

### TECHNICAL FIELD

Exemplary embodiments of the present disclosure relate to a plasma processing apparatus.

### BACKGROUND

A plasma processing apparatus is used in processing a substrate. As a type of plasma processing apparatus, an apparatus that excites gas using radio frequency waves such as very high frequency (VHF) waves or ultra high frequency (UHF) waves is known. Patent Document 1 below discloses such a plasma processing apparatus. The plasma processing apparatus of Patent Document 1 includes a processing container, a stage, an upper electrode, an introducer, and a waveguide portion. The stage is provided in the processing container. The upper electrode is provided above the stage with a space in the processing container interposed therebetween. The introducer is a radio frequency introducer. The introducer is provided at an end of the space in a lateral direction and extends in a circumferential direction around a central axis line of the processing container. The waveguide portion is configured to supply radio frequency waves to the introducer. The waveguide portion includes a resonator that provides a waveguide path. The waveguide path of the resonator extends circumferentially around the central axis line and extends in a direction in which the central axis line extends so as to be connected to the introducer.

### PRIOR ART DOCUMENTS

### Patent Documents

Patent Document 1: Japanese Patent Laid-Open Publication No. 2020-92031

### SUMMARY

According to one embodiment of the present disclosure, there is provided a plasma processing apparatus. The plasma processing apparatus includes: a chamber including a processing space inside the chamber; a substrate support installed in the processing space; an excitation electrode installed above the substrate support; a discharger configured to discharge electromagnetic waves into a plasma generation space below the excitation electrode; and a resonator installed on the excitation electrode and electromagnetically coupled to the discharger. The resonator includes a waveguide path including a plurality of folded portions between a first end and a second end of the resonator. The at least one adjustor configured to adjust a resonance frequency of the electromagnetic waves propagating in the waveguide path is installed in the waveguide path.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a diagram illustrating a plasma processing apparatus according to one exemplary embodiment.

FIG. 2 is a cross-sectional view taken along line II-II in FIG. 1.

FIG. 3 is a diagram illustrating a plasma processing apparatus according to another exemplary embodiment.

FIG. 4 is a cross-sectional view taken along line IV-IV in FIG. 3.

FIG. 5 is a diagram illustrating a plasma processing apparatus according to yet another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In each drawing, the same or corresponding configurations are denoted by the same reference numerals.

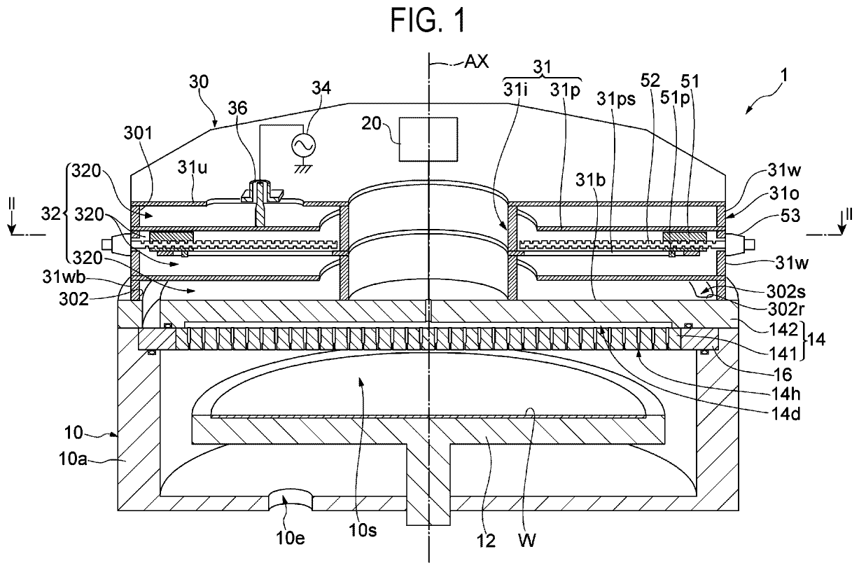

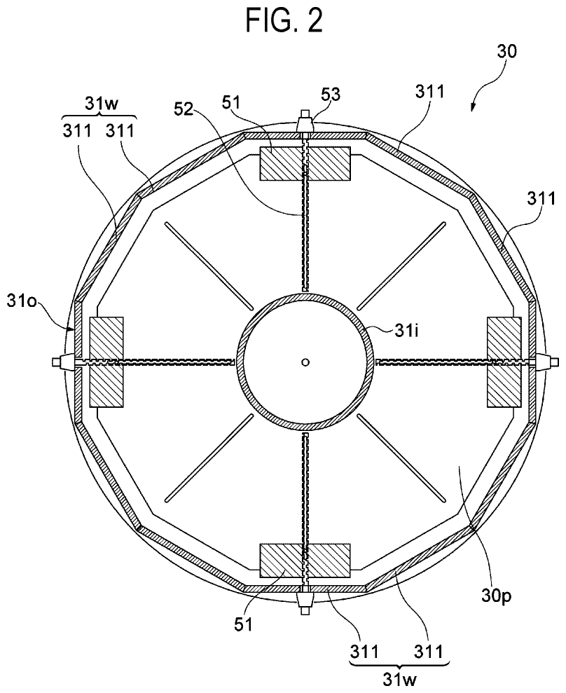

FIG. 1 is a diagram illustrating a plasma processing apparatus according to one exemplary embodiment. FIG. 2 is a cross-sectional view taken along line II-II in FIG. 1. A plasma processing apparatus 1 illustrated in FIGS. 1 and 2 includes a chamber 10, a substrate support 12, an excitation electrode 14, a discharger 16, and a resonator 30.

The chamber 10 includes a processing space 10s in the chamber 10. In the plasma processing apparatus 1, a substrate W is processed inside the processing space 10s. The chamber 10 is made of a metal such as aluminum and is grounded. The chamber 10 has a side wall 10a and is open at its upper end. The chamber 10 and the side wall 10a may have a substantially cylindrical shape. The processing space 10s is provided inside the side wall 10a. A central axis line of each of the chamber 10, the side wall 10a, and the processing space 10s is an axis line AX. The chamber 10 may have a corrosion-resistant film on the surface of the chamber 10. The corrosion-resistant film may be an yttrium oxide film, an yttrium oxide fluoride film, an yttrium fluoride film, or a ceramic film including yttrium oxide, yttrium fluoride, or the like.

An exhaust port 10e is formed in a bottom of the chamber 10. An exhaust device is connected to the exhaust port 10e. The exhaust device may include a vacuum pump, such as a dry pump and/or a turbomolecular pump, and an automatic pressure control valve.

The substrate support 12 is installed in the processing space 10s. The substrate support 12 is configured to substantially horizontally support the substrate W on an upper surface of the substrate support 12. The substrate support 12 has a substantially disc shape. A central axis line of the substrate support 12 is the axis line AX.

The excitation electrode 14 is installed above the substrate support 12 with the processing space 10s interposed therebetween. The excitation electrode 14 is made of a conductive material such as a metal (e.g., aluminum) and has a substantially disc shape. A central axis line of the excitation electrode 14 is the axis line AX.

The discharger 16 is installed to discharge electromagnetic waves therefrom into a plasma generation space. In the plasma processing apparatus 1, the plasma generation space is a space which is within the processing space 10s and is directly below the excitation electrode 14. The electromagnetic waves discharged from the discharger 16 into the plasma generation space may be radio frequency waves such as VHF waves or UHF waves. The discharger 16 is formed of a dielectric material such as quartz, aluminum nitride, or aluminum oxide. The discharger 16 extends in a circumferential direction around the axis line AX. The discharger 16 may have an annular shape. The discharger 16 may extend to surround the plasma generation space or a shower plate 141 described later. In the plasma processing apparatus 1, gas in the chamber 10 is excited by the electromagnetic waves discharged from the discharger 16 into the plasma generation space. As a result, plasma is generated in the plasma generation space.

In one embodiment, the excitation electrode 14 may include the shower plate 141 and an upper electrode 142. The shower plate 141 is provided on the plasma generation space. The shower plate 141 and the discharger 16 close the opening of the upper end of the chamber 10. The shower plate 141 includes a plurality of gas holes 14h. The plurality of gas holes 14h extends in a thickness direction (vertical direction) of the shower plate 141 and penetrates the shower plate 141.

The upper electrode 142 is installed on the shower plate 141. The upper electrode 142 forms a gas diffusion chamber 14d between the shower plate 141 and the upper electrode 142. A gas supply 20 is connected to the gas diffusion chamber 14d. The gas from the gas supply 20 is discharged into the plasma generation space (the processing space 10s) from the plurality of gas holes 14h via the gas diffusion chamber 14d.

The resonator 30 is installed on the excitation electrode 14. The resonator 30 is electromagnetically coupled to the discharger 16. The resonator 30 includes a waveguide path 32. The resonator 30 includes a conductive portion 31 that defines the waveguide path 32. The conductive portion 31 is made of a conductive material such as a metal. The conductive material forming the conductive portion 31 may include aluminum, stainless steel, copper, or brass.

The resonator 30 includes a first end 301 and a second end 302. The first end 301 is one end of the waveguide path 32, and the second end 302 is the other end of the waveguide path 32. The resonator 30 is configured to reflect electromagnetic waves propagating within the waveguide path 32 at the first end 301 and the second end 302 and cause the electromagnetic waves to resonate. The electromagnetic waves resonating in the resonator 30 are supplied to the discharger 16 from a plurality of slots 302s, which will be described later, and are discharged into the plasma generation space.

The plasma processing apparatus 1 may further include a radio frequency power source 34. The radio frequency power source 34 is configured to generate radio frequency power. The electromagnetic waves introduced into the plasma generation space is generated based on the radio frequency power generated by the radio frequency power source 34. The radio frequency power source 34 may be directly connected to the resonator 30 using a coaxial line. That is, the radio frequency power source 34 may be coupled to the waveguide path of the resonator 30 without using a matcher for impedance matching. The coaxial line may include a connector 36 as a connection portion to the resonator 30. The connector 36 may be connected to the resonator 30 so as to introduce the electromagnetic waves into the resonator 30 from the uppermost layer of a plurality of layers 320, which will be described later, of the waveguide path 32. In this case, an inner conductor of the connector 36 is connected to a conductive plate 31p, which will be described later, that defines the uppermost layer from below, and an outer conductor of the connector 36 is connected to a conductive plate 31p (upper wall 31u) that defines the uppermost layer from above.

In one embodiment, the waveguide path 32 may have a folded structure including a plurality of folded portions. In one embodiment, the waveguide path 32 may be configured axially or rotationally symmetrically with respect to the axis line AX. Further, in one embodiment, the conductive portion 31 may include an inner side portion 31i (or an inner peripheral portion), an outer side portion 310 (or an outer peripheral portion), and a plurality of conductive plates 31p. The inner side portion 31i and the outer side portion 310 extend coaxially with respect to the axis line AX. The plurality of conductive plates 31p extends radially with respect to the axis line AX and is arranged parallel to each other in the vertical direction, which is a direction in which the axis line AX extends.

Additionally, the waveguide path 32 may include the plurality of layers 320. The plurality of layers 320 extends in a radial direction with respect to the axis line AX between the inner side portion 31i and the outer side portion 310 and is arranged alternately with the plurality of conductive plates 31p. Each of the plurality of layers 320 is connected to a layer thereabove among the plurality of layers 320 at one of the plurality of folded portions along the inner side portion 31i or the outer side portion 310.

In one embodiment, the first end 301 is provided above the second end 302. The first end 301 is provided by the outer side portion 310 of the resonator 30. The first end 301 surrounds the uppermost layer of the plurality of layers 320. The second end 302 is composed of a wall 31wb of the outer side portion 310 surrounding a lowermost layer among the plurality of layers 320. The second end 302 extends in the circumferential direction around the axis line AX above the discharger 16. The plurality of slots 302s is formed in a lowermost conductive plate 31b that defines the lowermost layer from below among the plurality of conductive plates 31p. In the plasma processing apparatus 1, the conductive plate 31b also serves as the upper electrode 142. The plurality of slots 302s is disposed near the second end 302 or along the second end 302. The plurality of slots 302s is coupled to the discharger 16 from the outside of the excitation electrode 14. The plurality of slots 302s extends in a circumferential direction with respect to the axis line AX and is arranged in the circumferential direction. The plurality of slots 302s is arranged alternately with a plurality of portions 302r within the conductive plate 31b. In one embodiment, a radial distance between the axis line AX and an outer edge of each of the plurality of slots 30s may be substantially identical to a radius of an inscribed circle of a polygon of the wall 31wb. In this resonator 30, the electromagnetic waves at the second end 302 are reflected toward the first end 301. Further, some of the electromagnetic waves propagating in the resonator 30 are coupled to the discharger 16 through the plurality of slots 302s.

In the plasma processing apparatus 1, the inner side portion 31i may have a substantially cylindrical shape having a central axis of the axis line AX. The inner side portion 31i may be formed of a tubular (e.g., cylindrical) conductive wall extending between the conductive plates 31p which are adjacent in the vertical direction.

In the plasma processing apparatus 1, the outer side portion 310 has a substantially tubular shape and has the axis line AX as a central axis thereof. The outer side portion 310 may include a plurality of walls 31w including the wall 31wb surrounding the lowermost layer of the plurality of layers 320 and walls surrounding upper layers other than the lowermost layer among the plurality of layers 320. The plurality of walls 31w respectively extends between the corresponding conductive plates 31p adjacent to each other in the vertical direction and has a substantially tubular shape. The wall 31wb of the plurality of walls 31w surrounding at least the lowermost layer extends along sides of a polygon in a cross-section perpendicular to the axis line AX. Two or more or all of the walls 31w among the plurality of walls 31w may extend along the sides of the polygon in a cross-section perpendicular to the axis line AX. In one embodiment, the wall 31wb may have a polygonal tube shape. Further, each of two or more or all of the walls 31w among the plurality of walls 31w may have a polygonal tube shape. In addition, in the example illustrated in FIG. 1 and FIG. 2, the polygon is a regular dodecagon, but other polygons may be used as the polygon.

In one embodiment, the wall 31wb may be formed of a plurality of plate-like bodies 311. Further, each of two or more of the plurality of walls 31w or each of all of the walls 31w may be formed of the plurality of plate-like bodies 311. Each of the plurality of plate-like bodies 311 is formed of the above-mentioned metal. Each of the plurality of plate-like bodies 311 may be a flat plate. Each of the plurality of plate-like bodies 311 extends along a corresponding side of the above-mentioned polygon in a cross-section perpendicular to the axis line AX.

In the resonator 30, the magnitude of a current flowing into the conductive plate 31b in the radial direction with respect to the axis line AX has a distribution in a circumferential direction, in which the magnitude of the current is minimum in a direction from the axis line AX toward each corner of the above-mentioned polygon and is maximum at the center of each side of the above-mentioned polygon. Therefore, in each of the plurality of slots 302s, a distribution of electric field intensity is adjusted in the circumferential direction.

In one embodiment, the number of the plurality of slots 302s and the number of a plurality of corners of the polygon may be equal. Further, the position of each of the plurality of corners of the above-mentioned polygon and a center position of a corresponding slot in the circumferential direction among the plurality of slots 302s may be aligned in the radial direction with respect to the axis line AX. In this case, the magnitude of the current flowing into the conductive plate 31b in the radial direction has a distribution in the circumferential distribution, in which the magnitude of the current is weakened at the center of each of the plurality of slots 302s and is strengthened between adjacent slots 302s of the plurality of slots 302s. Therefore, in each of the plurality of slots 302s, uniformity of a distribution of electric field intensity in the circumferential direction is increased.

As illustrated in FIGS. 1 and 2, an edge of each of the plurality of plate-like bodies 311 extending in the vertical direction is connected to an edge of another corresponding plate-like body extending in the vertical direction among the plurality of plate-like bodies 311 at a corresponding corner of the above-mentioned polygon. However, the plurality of plate-like bodies 311 may be spaced apart from each other so as to form gaps at the corners of the above-mentioned polygon.

In the plasma processing apparatus 1, the resonator 30 further includes at least one adjustor. The at least one adjustor is configured to adjust a resonant frequency of the electromagnetic waves propagating in the waveguide path 32. In the plasma processing apparatus 1, the at least one adjustor is at least one dielectric 51. The at least one dielectric 51 changes an effective dielectric constant of the waveguide path 32 from an effective dielectric constant of the waveguide path 32 in which the at least one dielectric 51 is not provided in the waveguide path 32. The at least one dielectric 51 may be disposed at an intermediate position between the first end 301 and the second end 302 of the waveguide path 32. The at least one dielectric 51 may have a rectangular parallelepiped shape. The at least one dielectric 51 may have another shape.

In the plasma processing apparatus 1, the resonator 30 further includes at least one guider 52. The at least one guider 52 is configured to guide the at least one dielectric 51 in the radial direction with respect to the axis line AX.

In the example illustrated in FIGS. 1 and 2, the resonator 30 includes a plurality of dielectrics 51 as the at least one dielectric 51 and includes a plurality of guiders 52 as the at least one guider 52. The plurality of guiders 52 is disposed rotationally symmetrically around the axis line AX. The plurality of guiders 52 is configured to respectively guide the plurality of dielectrics 51 in a plurality of radial directions that is rotationally symmetrical around the axis line AX. The plurality of radial directions may be directions at equal intervals in the circumferential direction.

Each of the plurality of guiders 52 may include, for example, a ball screw extending in a corresponding radial direction among the plurality of radial directions. Each of the plurality of dielectrics 51 is installed on the ball screw of the corresponding guider 52 and is movable in the radial direction by a driver 53. The driver 53 may be an operator such as a handle that is operated manually. Alternatively, the driver 53 may be composed of an actuator, such as a stepper motor, and a controller.

Each of the plurality of dielectrics 51 may include a protrusion 51p. In this case, a plurality of slits 31ps extending in the radial direction below each of the plurality of guiders 52 is formed in the conductive plate 31p which defines, from below, a layer in which the dielectric 51 is disposed among the plurality of layers 320. The protrusions 51p of each of the plurality of dielectrics 51 are respectively disposed within the plurality of slits 31ps. The plurality of dielectrics 51 and the plurality of guiders 52 may be made of an insulator such as alumina ceramics, quartz, or tetrafluoroethylene.

In this plasma processing apparatus 1, it is possible to adjust the effective dielectric constant of the waveguide path 32 by the plurality of dielectrics 51. Therefore, according to the plasma processing apparatus 1, it is possible to adjust a resonance frequency in the resonator 30. Additionally, since the position of each of the plurality of dielectrics 51 in the radial direction is changeable by the plurality of guiders 52, it is also possible to change the resonance frequency in the resonator 30. Further, the effective dielectric constant of the waveguide path 32 may be maximized by disposing the plurality of dielectrics 51 at an intermediate position between the first end 301 and the second end 302 of the waveguide path 32. As a result, it is possible to reduce (or change) the resonance frequency in the resonator 30 to the maximum.

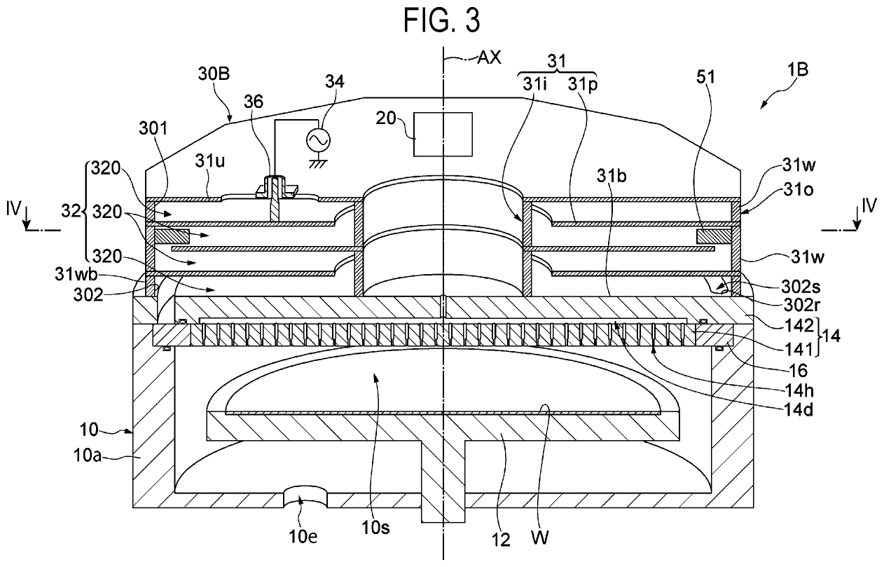

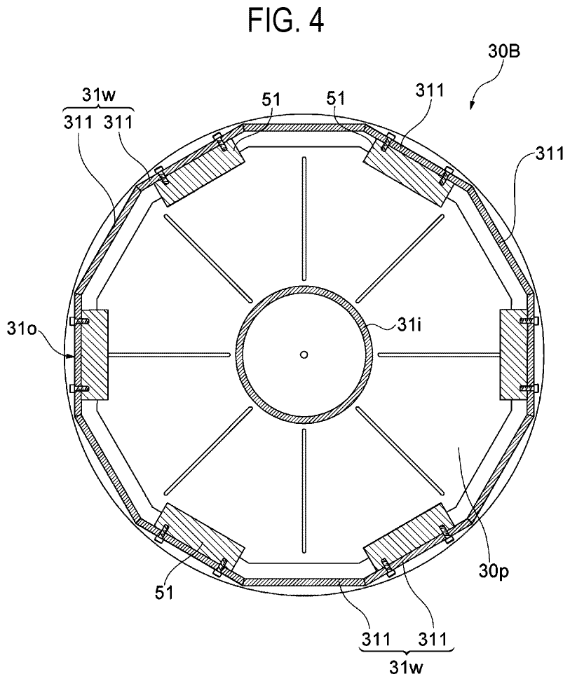

Hereinafter, a plasma processing apparatus according to another exemplary embodiment will be described with reference to FIGS. 3 and 4. FIG. 3 is a diagram illustrating a plasma processing apparatus according to another exemplary embodiment. FIG. 4 is a cross-sectional view taken along line IV-IV in FIG. 3. Hereinafter, a plasma processing apparatus 1B illustrated in FIGS. 3 and 4 will be described from the viewpoint of differences from the plasma processing apparatus 1.

The plasma processing apparatus 1B is provided with a resonator 30B instead of the resonator 30. Like the resonator 30 of the plasma processing apparatus 1, the resonator 30B also includes the plurality of dielectrics 51 as the at least one dielectric 51. The resonator 30B does not include the plurality of guiders 52. In the resonator 30B, the plurality of dielectrics 51 may be disposed at an intermediate position between the first end 301 and the second end 302 of the waveguide path 32. Additionally, the plurality of dielectrics 51 is detachably fixed to the wall 31w that defines the outer side portion 310. Each of the plurality of dielectrics 51 is fixed to the wall 31w by, for example, one or more screws.

In addition, in the resonator 30B, the plurality of dielectrics 51 may be respectively disposed at multiple locations rotationally symmetrical around the axis line AX. The plurality of dielectrics 51 may be disposed at equal intervals in the circumferential direction with respect to the axis line AX. Additionally, the other configurations in the plasma processing apparatus 1B are the same as corresponding configurations in the plasma processing apparatus 1.

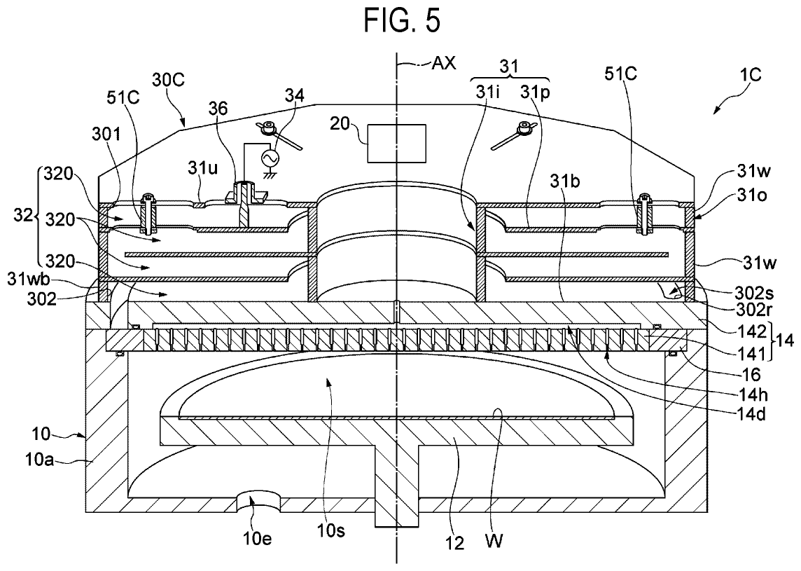

Hereinafter, a plasma processing apparatus according to yet another exemplary embodiment will be described with reference to FIG. 5. FIG. 5 is a diagram illustrating a plasma processing apparatus according to yet another exemplary embodiment. Hereinafter, a plasma processing apparatus 1C illustrated in FIG. 5 will be described from the viewpoint of differences from the plasma processing apparatus 1.

The plasma processing apparatus 1C is provided with a resonator 30C instead of the resonator 30. The resonator 30C includes at least one spacer 51C as the at least one adjustor. The at least one spacer 51C is made of a metal such as aluminum, stainless steel, or copper. The at least one spacer 51C may have a pillar shape. The at least one spacer 51C is disposed between the first end 301 and the second end 302 within the waveguide path 32. The at least one spacer 51C is disposed closer to the first end 301 than the second end 302. The at least one spacer 51C may be disposed in the uppermost layer of the plurality of layers 320.

The resonator 30C may include a plurality of spacers 51C as the at least one spacer 51C. The plurality of spacers 51C may be disposed rotationally symmetrically with respect to the axis line AX in the uppermost layer among the plurality of layers 320. The plurality of spacers 51C may be disposed at equal intervals in the circumferential direction with respect to the axis line AX.

The plurality of spacers 51C may be installed to be movable in a plurality of radial directions rotationally symmetrical with respect to the axis line AX in the waveguide path 32 or in a plurality of radial directions at equal intervals in the circumferential direction with respect to the axis line AX in the waveguide path 32. In one embodiment, a plurality of slits extending in a plurality of radial directions is formed in each of the upper wall 31u that defines the uppermost layer from above and the conductive plate 31p that defines the uppermost layer from below. In this case, each of the plurality of spacers 51C may have a tube shape. A screw extending through a slit of the upper wall 31u and a corresponding slit of the conductive plate 31p passes through an inner hole of each of the plurality of spacers 51C. The screw is screwed to a nut disposed below the conductive plate 31p. Each of the plurality of spacers 51C is held with and fixed to the upper wall 31u and the conductive plate 31p by a head of the screw and the nut. Additionally, in the resonator 30C, the screw is moved along the slit of the upper wall 31u and the corresponding slit of the conductive plate 31p, and the corresponding spacer 51C is moved together with the screw, so that the spacer 51C can be moved in the radial direction. In addition, the other configurations of the plasma processing apparatus 1C are the same as the corresponding configurations of the plasma processing apparatus 1.

In the plasma processing apparatus 1C, a position at which electromagnetic waves are reflected near the first end 301 can be adjusted by the plurality of spacers 51C. Therefore, according to the plasma processing apparatus 1, it is possible to adjust a resonance frequency in the resonator 30C. Additionally, it is possible to change the position at which the electromagnetic waves are reflected near the first end 301 by moving the plurality of spacers 51C in the radial direction. Therefore, according to the plasma processing apparatus 1, it is possible to change the resonance frequency in the resonator 30C.

While various exemplary embodiments have been described above, the present disclosure is not limited to the above-described exemplary embodiments, and various additions, omissions, substitutions, and changes may be made. In addition, it is possible to form other embodiments by combining elements from other embodiments.

For example, in the plasma processing apparatus of the various exemplary embodiments described above, the wall of the outer side portion 310 may have a substantially cylindrical shape. Additionally, each of the plurality of layers 320 constituting the waveguide path 32 may have a tube shape, and these layers 320 may be stacked in the radial direction with respect to the axis line AX. That is, the plurality of layers 320 may be arranged coaxially with respect to the axis line AX.

According to the present disclosure in some embodiments, it is possible to adjust a resonance frequency in a resonator of a plasma processing apparatus.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus, comprising:
a chamber including a processing space inside the chamber;
a substrate support installed in the processing space;
an excitation electrode installed above the substrate support;
a discharger configured to discharge electromagnetic waves into a plasma generation space below the excitation electrode; and
a resonator installed on the excitation electrode and electromagnetically coupled to the discharger,
wherein the resonator includes a waveguide path including a plurality of folded portions between a first end and a second end of the resonator, and
wherein at least one adjustor configured to adjust a resonance frequency of the electromagnetic waves propagating in the waveguide path is installed in the waveguide path.

2. The plasma processing apparatus of claim 1, wherein the at least one adjustor includes at least one dielectric having a dielectric constant different from a dielectric constant in other portions of the waveguide path, and
wherein the at least one dielectric is disposed at an intermediate position between the first end and the second end of the waveguide path.

3. The plasma processing apparatus of claim 2, wherein the discharger extends around a central axis line of the chamber and the excitation electrode,
wherein the resonator includes:
an inner side portion and an outer side portion extending coaxially with respect to the central axis line, and
a plurality of conductive plates arranged parallel to each other in a vertical direction, which is a direction in which the central axis line extends,
wherein the resonator includes the waveguide path extending between the outer side portion and the inner side portion and including a plurality of layers arranged alternately with the plurality of conductive plates,
wherein each of the plurality of layers is connected to a layer thereabove among the plurality of layers at one of the plurality of folded portions along the inner side portion or the outer side portion;
wherein a lowermost conductive plate among the plurality of conductive plates includes a plurality of slots electromagnetically coupled to the discharger, and
wherein the plurality of slots is arranged in a circumferential direction with respect to the central axis line.

4. The plasma processing apparatus of claim 3, wherein the resonator further includes at least one guider configured to guide the at least one dielectric in a radial direction with respect to the central axis line.

5. The plasma processing apparatus of claim 4, wherein the resonator includes a plurality of dielectrics as the at least one dielectric and a plurality of guiders arranged rotationally symmetrically around the central axis line as the at least one guider, and
wherein the plurality of guiders is configured to respectively guide the plurality of dielectrics in the radial direction.

6. The plasma processing apparatus of claim 3, wherein the at least one dielectric is disposed within the waveguide path and is detachably fixed to the outer side portion.

7. The plasma processing apparatus of claim 6, wherein the resonator includes a plurality of dielectrics as the at least one dielectric, and
wherein the plurality of dielectrics is respectively disposed at a plurality of locations rotationally symmetrical around the central axis line within the waveguide path and is detachably fixed to the outer side portion.

8. The plasma processing apparatus of claim 7, wherein the at least one dielectric changes an effective dielectric constant of the waveguide path.

9. The plasma processing apparatus of claim 2, wherein the at least one dielectric changes an effective dielectric constant of the waveguide path.

10. The plasma processing apparatus of claim 1, wherein the at least one adjustor includes at least one spacer of a metal disposed between the first end and the second end.

11. The plasma processing apparatus of claim 10, wherein the discharger extends around a central axis line of the chamber and the excitation electrode,
wherein the resonator includes:
an inner side portion and an outer side portion extending coaxially with respect to the central axis line; and
a plurality of conductive plates arranged parallel to each other in a vertical direction, which is a direction in which the central axis line extends,
wherein the resonator includes the waveguide path extending between the outer side portion and the inner side portion and including a plurality of layers arranged alternately with the plurality of conductive plates,
wherein each of the plurality of layers is connected to a layer thereabove among the plurality of layers at one of the plurality of folded portions along the inner side portion or the outer side portion;
wherein a lowermost conductive plate among the plurality of conductive plates includes a plurality of slots electromagnetically coupled to the discharger, and
wherein the plurality of slots is arranged in a circumferential direction with respect to the central axis line.

12. The plasma processing apparatus of claim 11, wherein the resonator includes a plurality of spacers as the at least one spacer, and
wherein the plurality of spacers is disposed rotationally symmetrically with respect to the central axis line within an uppermost layer among the plurality of layers.

13. The plasma processing apparatus of claim 12, wherein the at least one spacer is installed to be movable in a radial direction with respect to the central axis line in the waveguide path.

14. The plasma processing apparatus of claim 11, wherein the at least one spacer is installed to be movable in a radial direction with respect to the central axis line in the waveguide path.

15. A plasma processing apparatus, comprising:
a chamber including a processing space inside the chamber;
a substrate support installed in the processing space;
an excitation electrode installed above the substrate support;
a discharger configured to discharge electromagnetic waves into a plasma generation space below the excitation electrode; and
a resonator installed on the excitation electrode and electromagnetically coupled to the discharger,
wherein the resonator includes:
a waveguide path including a plurality of folded portions between a first end and a second end of the resonator; and
at least one dielectric having a dielectric constant different from a dielectric constant in other portions of the waveguide path, and disposed at an intermediate position between the first end and the second end of the waveguide path.

16. The plasma processing apparatus of claim 15, wherein the discharger extends around a central axis line of the chamber and the excitation electrode,
wherein the resonator includes:
an inner side portion and an outer side portion extending coaxially with respect to the central axis line, and
a plurality of conductive plates arranged parallel to each other in a vertical direction, which is a direction in which the central axis line extends,
wherein the resonator includes the waveguide path extending between the outer side portion and the inner side portion and including a plurality of layers arranged alternately with the plurality of conductive plates,
wherein each of the plurality of layers is connected to a layer thereabove among the plurality of layers at one of the plurality of folded portions along the inner side portion or the outer side portion;
wherein a lowermost conductive plate among the plurality of conductive plates includes a plurality of slots electromagnetically coupled to the discharger, and
wherein the plurality of slots is arranged in a circumferential direction with respect to the central axis line.

17. The plasma processing apparatus of claim 16, wherein the resonator further includes at least one guider configured to guide the at least one dielectric in a radial direction with respect to the central axis line.

18. The plasma processing apparatus of claim 17, wherein the resonator includes a plurality of dielectrics as the at least one dielectric and a plurality of guiders arranged rotationally symmetrically around the central axis line as the at least one guider, and
wherein the plurality of guiders is configured to respectively guide the plurality of dielectrics in the radial direction.

19. The plasma processing apparatus of claim 16, wherein the at least one dielectric is disposed within the waveguide path and is detachably fixed to the outer side portion.

20. The plasma processing apparatus of claim 19, wherein the resonator includes a plurality of dielectrics as the at least one dielectric, and
wherein the plurality of dielectrics is respectively disposed at a plurality of locations rotationally symmetrical around the central axis line within the waveguide path and is detachably fixed to the outer side portion.
